(19) United States
(12) Patent Application Publication
(10) Pub. No.: US 2023/0059730 A1
(43) Pub. Date: Feb. 23, 2023

(54) ATOMIC-SCALE MATERIALS PROCESSING BASED ON ELECTRON BEAM INDUCED ETCHING ASSISTED BY REMOTE PLASMA

(71) Applicant: UNIVERSITY OF MARYLAND, COLLEGE PARK, College Park, MD (US)

(72) Inventors: Gottlieb S. OEHRLEIN, Clarksville, MD (US); Kang-Yi LIN, Greenbelt, MD (US)

(21) Appl. No.: 17/891,491

(22) Filed: Aug. 19, 2022

Related U.S. Application Data
(60) Provisional application No. 63/234,965, filed on Aug. 19, 2021.

(51) Int. Cl. H01J 37/305; H01J 37/32

(52) U.S. Cl. CPC H01J 37/3053; H01J 37/32357; H01J 2237/338

(57) ABSTRACT

Systems, methods, and apparatuses for atomic-scale materials processing based on electron beam induced etching assisted by remote plasma are disclosed. For example, a method may include placing the substrate into a low-pressure chamber to which an electron source is connected. The method may also include contacting the surface of the substrate with reactive particle fluxes produced by a remote plasma source connected to the low-pressure chamber. The remote plasma source may be fed with one or more chemical precursors for surface chemical functionalization of the surface of the substrate. The method may further include electron irradiation of the surface of the substrate with electrons via the electron source at a specified energy level to induce a surface chemical process on the surface of the substrate.

### CROSS-REFERENCE TO RELATED APPLICATION

This application claims priority from U.S. provisional patent application No. 63/234,965 filed on Aug. 19, 2021. The contents of this earlier filed application are hereby incorporated by reference in their entirety.

### FIELD

The present disclosure generally relates to substrate etching. For example, certain embodiments described in the present disclosure generally may relate to apparatuses, systems, and/or methods for atomic-scale materials processing based on electron beam induced etching assisted by remote plasma.

### BACKGROUND

Plasma etching is an application of plasma treatment, and plasma etching may be used in the production of various semiconductor devices. During plasma etching, highly energetic and reactive species produced from a selected process gas, such as O₂ or fluorine bearing gas, bombard and react with a sample surface. As a result, the atomic constituents of the materials at the surface are broken down to form volatile and/or smaller molecules which are pumped away in a vacuum system. Thus, it may be possible to etch off parts, or the entire top layer of the sample surface.

As the feature size of transistors in a semiconductor chip continues to decrease to the sub-10 nm range, plasma etching for pattern transfer may be needed to achieve atomistic resolution with ultrahigh etch selectivity between different materials. Such etching may be performed by, for example, atomic layer etching (ALE) processes. Conventionally, ALE processes may use plasma operated in a cyclic sequence and may consist of reactant-based surface functionalization and etching steps. In the surface functionalization step, a controlled amount of precursor may deposit reactants on a substrate and/or tailor the surface property of a substrate. Additionally, in the etching step, low-energy ions sputter the deposited reactant and functionalized layers through ion-enhanced chemical removal. Since the applied ion energy is below the sputter energy threshold of the unreacted layer, once the ions remove all the surface-functionalized material, etching will stop. Etch selectivity may be achieved using the chemical affinity between the constituents of the chemical precursors and the substrate material. For ALE of SiO₂ with selectivity to Si, a deposition step with C₄F₈ and the etch step based on low-energy Ar ion bombardment is one possible approach, and enables etching selectivity based on the concept that SiO₂ may consume fluorocarbon faster than Si under a certain optimized condition.

However, with conventional ALE processes based on plasma functionalization followed by ion bombardment, plasma intrinsically develops a sheath potential on a substrate, resulting in inevitable material loss and damage, and defects by ion bombardment (e.g., atomic displacement defects, or formation of modified layers). For example, for C₄F₈-based ALE it has been shown that a −15 V sheath potential produced in this way leads to SiO₂ and Si losses at the beginning of the deposition step. Moreover, exposure of SiO₂ and other soft materials to an Ar plasma creates defects or extra layers, including the displacement of atoms and the formation of another surface layer that decreases pattern transfer fidelity. Therefore, direct plasma exposure of a substrate even to a plasma for which the energy of bombarding ions has been reduced to a very narrow range is not ideal for achieving an ALE process with minimal substrate defects since it is accompanied by displacement damage. Accordingly, there is a need to utilize lighter and tightly energy-controlled particles that can volatilize the functionalized layer at a substrate for addressing the aforementioned challenges and avoid defect introduction.

### SUMMARY

Some example embodiments may be directed to a method. The method may include placing the substrate into a low-pressure chamber to which an electron source is connected. The method may also include contacting the surface of the substrate with reactive particle fluxes produced by a remote plasma source connected to the low-pressure chamber. According to certain example embodiments, the remote plasma source may be fed with one or more chemical precursors for surface chemical functionalization of the surface of the substrate. The method may further include electron irradiating the surface of the substrate with electrons via the electron source at a specified energy level to induce a surface chemical process on the surface of the substrate.

Other example embodiments may be directed to an apparatus for treating a surface of a substrate. The apparatus may include an electron source configured to irradiate the surface of the substrate with electrons at a specified energy level to induce a surface chemical process on the surface of the substrate. The apparatus may also include a remote plasma source configured to supply reactive particle fluxes to contact the surface of the substrate. According to certain example embodiments, the remote plasma source may be fed with one or more chemical precursors for surface chemical functionalization of the surface of the substrate. The apparatus may further include a differential pumping unit disposed at an outlet of the electron source. In addition, the apparatus may include a neutralization or optical isolation plate adjacent to the remote plasma source.

Other example embodiments may be directed to an apparatus for treating a surface of a substrate. The apparatus may include means for placing a substrate into a low-pressure chamber to which an electron source is connected. The apparatus may also include means for contacting the surface of the substrate with reactive particle fluxes produced by a remote plasma source connected to the low-pressure chamber. According to certain example embodiments, the remote plasma source may be fed with one or more chemical precursors for surface chemical functionalization of the surface of the substrate. The apparatus may further include means for electron irradiating the surface of the substrate with electrons via the electron source at a specified energy level to induce a surface chemical process on the surface of the substrate.

### BRIEF DESCRIPTION OF THE DRAWINGS

For the proper understanding of example embodiments, reference should be made to the accompanying drawings, wherein:

FIG. 1 illustrates an example reactor, according to certain embodiments.

FIG. 2 illustrates an example atomic layer etching sequence, according to certain embodiments.

FIG. 3 illustrates an example SiO₂ thickness profile after the procedure of FIG. 2, according to certain embodiments.

FIG. 4 illustrates an example processing sequence for SiO₂, according to certain embodiments.

FIG. 5 illustrates an example SiO₂ thickness profile, according to certain embodiments.

FIG. 6 illustrates an example of etch selectivity of Si₃N₄ over SiO₂ for various CF₄/O₂ ratios, according to certain embodiments.

FIG. 7 illustrates an example flow diagram of a method, according to certain example embodiments.

### DETAILED DESCRIPTION

It will be readily understood that the components of certain example embodiments, as generally described and illustrated in the figures herein, may be arranged and designed in a wide variety of different configurations. The following is a detailed description of some example embodiments of systems, methods, and apparatuses for the realization of atomic-scale materials processing based on electron beam induced etching assisted by remote plasma.

The features, structures, or characteristics of example embodiments described throughout this specification may be combined in any suitable manner in one or more example embodiments. For example, the usage of the phrases “certain embodiments,” “an example embodiment,” “some embodiments,” or other similar language, throughout this specification refers to the fact that a particular feature, structure, or characteristic described in connection with an embodiment may be included in at least one embodiment. Thus, appearances of the phrases “in certain embodiments,” “an example embodiment,” “in some embodiments,” “in other embodiments,” or other similar language, throughout this specification do not necessarily refer to the same group of embodiments, and the described features, structures, or characteristics may be combined in any suitable manner in one or more example embodiments.

Certain embodiments may utilize electron beam (EB) with the assistance of remote plasma to achieve damage-free etching at the atomic scale, including, for example, atomic layer etching (ALE). According to certain embodiments, remote plasma may correspond to the configuration in which plasma is generated remotely relative to the reactor chamber used for processing, and the neutrals produced by the plasma reach the reactor chamber. The remote plasma may also be known as downstream plasma and/or afterglow plasma. Furthermore, in certain embodiments, “remote” may refer to guaranteeing charge-free particle flux, which may be achieved by using a charge neutralization plate. However, in other embodiments, charge-free particle flux may also be achieved by other means. According to some embodiments, by applying remote plasma, it may be possible to provide optical isolation to prevent vacuum ultraviolet (VUV) photons from the plasma to bombard the surface. In other embodiments, some remote plasma sources may not need to use a neutralization plate, and may instead use a long L-shaped tube that connects a remote plasma source and a reactor for the surface treatment. In doing so, it may be possible to avoid the effect of VUV and ion bombardment. This configuration may also allow a remote plasma source to be located remotely relative to a reactor. Other embodiments may provide subsequent EB irradiation that may achieve the removal of the reacted SiO₂ in a self-limited fashion. Additionally, certain embodiments may implement a cyclic process using these steps to achieve ALE of SiO₂ without damaging the underlying material. For instance, in some example embodiments, the etching may be limited to the size of a focused electron beam.

According to certain embodiments, the action of an EB source and a remote plasma source may be combined for realizing highly effective etching. For instance, certain embodiments may provide improved control with regard to materials chemistry by enabling independent control of surface chemistry/functionalization using the remote plasma source. Additionally, in some embodiments, etching may be controlled by the EB source that may serve to initiate etching by providing electrons of suitable energy directly to the surface of the substrate. In this fashion, etching may be controlled temporally and spatially by controlling the EB bombardment. As such, certain embodiments may enable damage-free ALE and maximize the number of materials that may be etched, and/or materials etching selectivity, by increasing the number of available chemical precursors for electron beam-inducing etching (EBIE).

Certain embodiments may provide a system that integrates a source of mono-energetic electrons and a remote plasma source for an ALE process. According to certain embodiments, a remote plasma may selectively tailor the surface properties of the substrate by chemical functionalization, and subsequent EB bombardment may be applied to remove the reacted surface layer. Additionally, certain embodiments may incorporate a cyclic process of these steps to realize an ALE process. Since the mass of electrons is approximately ˜ 1/100,000 of the mass of Ar⁺ ions, an advantage of using an energetic EB rather than Ar⁺ ions is the elimination of atomic displacement and defect introduction that may accompany plasma-based ALE.

According to certain embodiments, a variety of chemical precursors may be provided for EBIE. On the other hand, conventional EBIE processes may require a precursor that absorbs on a substrate, and electron-stimulated desorption (ESD) removes the adsorbates and the reacted layer. This technique may be used in scanning electron microscopy (SEM) that rasters the substrate with the assistance of reactive precursors to repair a defective photomask. However, the number of suitable precursor-substrate combinations is limited, whereas the number of chemical precursors useful in plasma etching is much larger. A reason for this is that most chemical precursors are hardly adsorbed on the substrate surface at room temperature owing to their stable nature. For example, NF₃ may provide near-zero surface coverage, whereas CF₄ may have good adsorption on a substrate. However, instead of etching, CF₄ may tend to form a fluorocarbon film under the irradiation of electron beams.

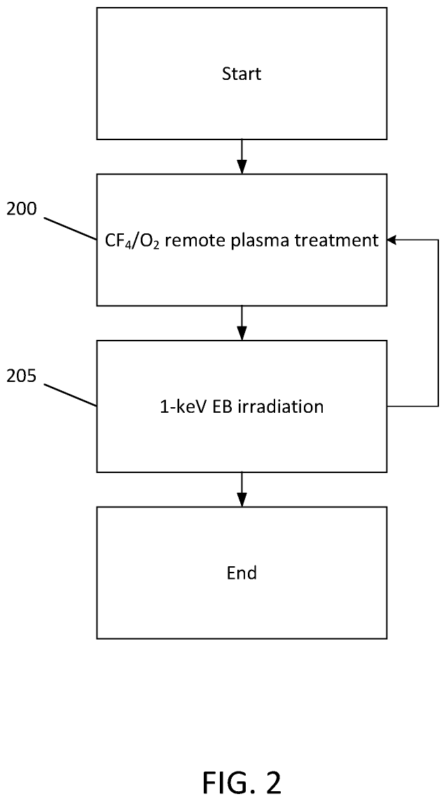

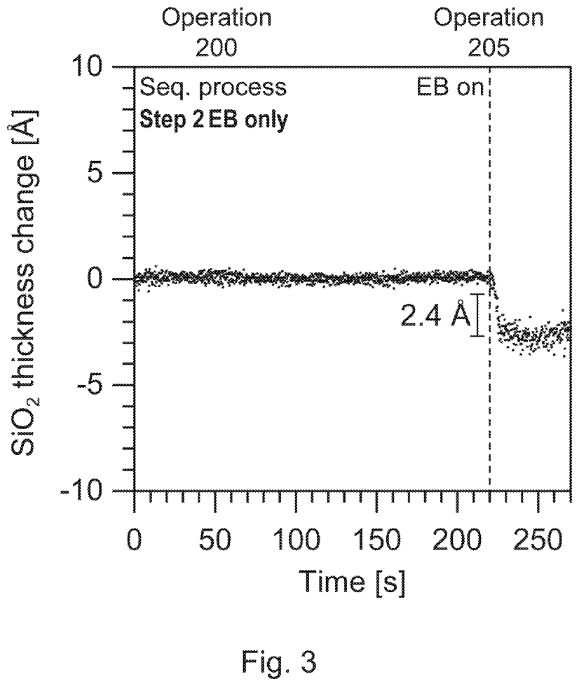

In contrast to conventional processes, certain embodiments may integrate a remote plasma source and an EB system to decouple surface functionalization and product removal steps. For instance, the remote plasma may be provided to dissociate injected precursors to improve the adsorption of reactants on the surface of a substrate. The remote plasma source may also provide the ability to tailor the surface functionalization which one cannot easily achieve without a plasma. For instance, surface coverage may be changed by low temperature, but would not allow changes in the chemical composition of the adsorbed surface layer as remote plasma generated fluxes do. According to certain embodiments, by controlling the effective surface chemistry, it may be possible to implement remote plasma without material removal. For instance, in some embodiments, certain conditions may be selected to avoid spontaneous etching of the substrate. For instance, in some embodiments, the examples illustrated in FIGS. 2 and 3 may use conditions that may include the remote plasma parameter of a 400 W source power, 1.8 mT static magnetic field, and Ar/CF₄/O₂ precursors at a flow rate of 10/1/4 sccm with a 1.8 mTorr processing pressure. According to other embodiments, another condition may include the use of a fixed total flow rate of reactants (e.g., CF₄+O₂=5 sccm), and varying the O₂ to CF₄ ratio from 10% to 90%, which also shows no SiO₂ etch, and only tailors its surface property. On the other hand, chemical precursors that previously may not have been applied to support EBIE may be feasible to support etching in this approach. In certain embodiments, a combination of precursors in this setup may demonstrate the capability for improving the etch selectivity for repairing a defective photomask through EBIE.

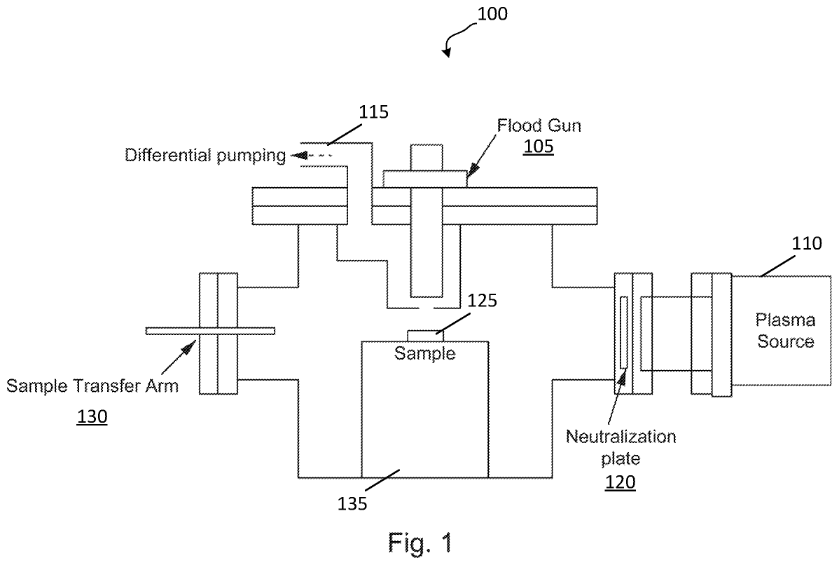

FIG. 1 illustrates an example reactor 100, according to certain embodiments. In certain embodiments, the example reactor 100 illustrated in FIG. 1 may integrate an electron source such as, for example, a flood gun 105 (i.e., electron source; electron flood gun), sample 125 held by a sample holder 135 that regulates specimen temperature and bias, sample transfer arm 130 to transport the sample, and a plasma source 110. According to certain embodiments, the plasma source 110 may correspond to a remote plasma source. In certain embodiments, the temperature-controlled function may control the reaction temperature ranging from 5° C. to 90° C. Furthermore, the substrate bias may manage the landing energy of an electron beam. For example, an electron gun may emit 1,000 eV electron beams on a +100 VDC biased substrate, delivering the 1,100 eV electrons on a specimen.

According to certain embodiments, the flood gun 105 may include a volume that is evacuated to a very low pressure, including ultrahigh vacuum (UHV), e.g. as realized in FIG. 1 by a differential pumping unit 115 connected to the flood gun 105 that may be used to prolong the filament lifetime when in contact with the process chamber where the partial pressure of reactive gases/fragments may be significant. However, in other embodiments, the pumping unit that is necessary to establish a pressure differential between the electron source chamber and the reaction chamber where the substrate to be processed is located, may be omitted for other types of electron sources. According to certain embodiments, the differential pumping unit 115 may create a pressure difference between an interior space of the differential pumping unit 115 into which the flood gun 105 may be disposed, and the interior space of the reactor 100. In some embodiments, the plasma source 110 may not be needed for other types of electron sources. As illustrated in FIG. 1, the plasma source 110 may be installed on a side port of the reactor 100 and may include an electron cyclotron wave resonance (EWCR) (e.g., plasma source 110) source and a neutralization plate 120. In certain embodiments, the neutralization plate 120 may eliminate ions and only allow for neutrals to diffuse onto the sample. In other embodiments, the neutralization plate 120 may be replaced by a L-shape tubing or two magnets as ion filters. In further embodiments, any type of source for which energetic particles that would compete with the energy delivery of the electron beam (e.g., charged particles such as ions or other electrons), or energetic photons, has been eliminated, and that serves for chemical surface functionalization, may be suitable. According to certain embodiments, the type of plasma source 110 may be flexible and may be based on radio frequencies (RFs), microwaves, or other types of power used for plasma excitation. The location of the plasma source 110 is also flexible and the reactive particle fluxes of the plasma source may be supplied to the substrate surface for surface functionalization while minimizing charged particle exposure.

The etching process of certain embodiments may be based on a sequential etching approach or a simultaneous etching approach. In the sequential etching approach, sequential surface treatments of exposure to the plasma source 110 may be performed followed by EB irradiation using the flood gun 105. The simultaneous etching approach may involve material etching based on simultaneous exposure of the sample surface to the chemical species flux produced by the plasma source 110, and energetic electrons from the electron source (e.g., EB irradiation; flood gun 105).

FIG. 2 illustrates an example atomic layer etching sequence, according to certain embodiments. In particular, FIG. 2 illustrates an example atomic layer etching sequence on a SiO₂ sample suitable for ALE applications. At 200, the Ar/CF₄/O₂ remote plasma may be utilized to generate a fluorinated layer on the SiO₂ sample surface. At 205, a 1-keV EB may be applied to irradiate the functionalized SiO₂ surface. According to certain embodiments, the parameters of the remote plasma may include a 400 W source power, 1.8 mT static magnetic fields, and Ar/CF₄/O₂ precursors at a flow rate of 10/1/4 sccm with a 1.8 mTorr processing pressure. According to other embodiments, the parameters of the EB (e.g., energies) may include electron energy between 10 eV to 30 keV. Alternatively, in other embodiments, the electron energy may be between 10 eV or less.

FIG. 3 illustrates an example SiO₂ thickness profile after the procedure of FIG. 2, according to certain embodiments. As illustrated in FIG. 3, the first 100-second treatment by the Ar/CF₄/O₂ remote plasma did not result in any SiO₂ loss. The following EB irradiation of the treated SiO₂ surface at the processing time corresponding to 220 seconds resulted in the removal of 2.4 Å SiO₂, and the etching stopped once EB depleted the fluorinated SiO₂ layer. According to certain embodiments, by repeating the cycle (e.g., operations 200 and 205), the remote plasma-assisted EB may achieve a self-limited ALE process for SiO₂.

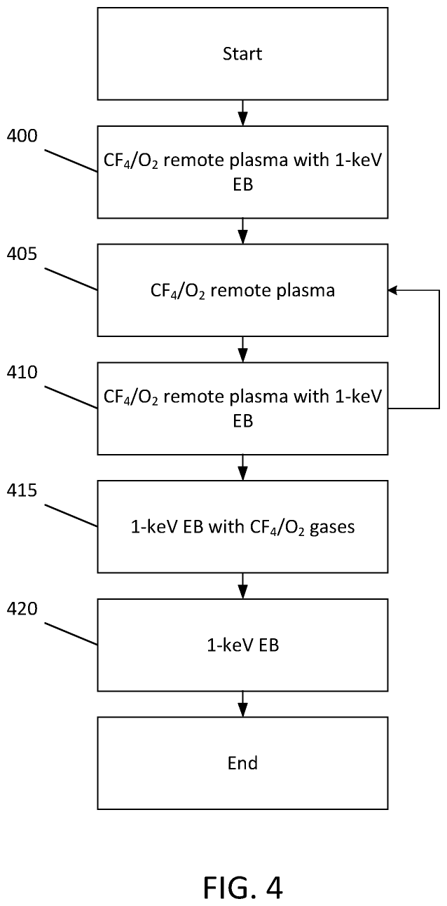

In certain embodiments, a surface may be simultaneous to the energetic EB and the chemical flux from the remote plasma to realize EBIE. For instance, FIG. 4 illustrates an example processing sequence for SiO₂, according to certain embodiments. The process may include the co-introduction of remote plasma and EB (operations 400 and 410, and at 410 again when the cycle repeats), the Ar/CF₄/O₂ remote plasma (operation 405, and 405 again when the cycle repeats), Ar/CF₄/O₂ precursors and EB (operation 415), and then EB only (operation 420). In performing the procedure of FIG. 4, it may be possible to validate the role of EB that enhances the removal rate of the adsorbates generated on the SiO₂ sample and the effect of remote plasma that improves the surface adsorption of reactants. For example, at operation 420, a 1-keV EB may be deployed to irradiate SiO₂ to review any thickness loss by EB. In certain embodiments, the processing parameters of the remote plasma may remain the same as described above.

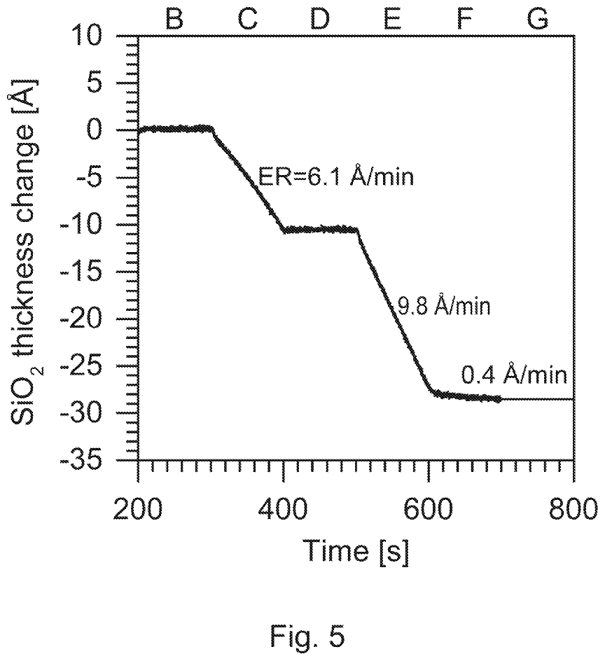

FIG. 5 illustrates an example SiO₂ thickness profile, according to certain embodiments. In particular, FIG. 5 illustrates the SiO₂ thickness profile after performing the processing sequence illustrated in FIG. 4 where operation 400 was a surface cleaning step used to remove ambient contamination that naturally deposited on the SiO₂ surface and is not included. As illustrated in FIG. 5, in the plasma operations (operations 405 and 410, shown as B and C in FIG. 5), the SiO₂ thickness remained constant throughout B to the beginning of C, suggesting that the use of the Ar/CF₄/O₂ remote plasmas did not cause material loss and primarily functionalized the SiO₂ surface. For comparison, during co-exposure of the SiO₂ surface to radicals and electron bombardment (operation 410 during the initial and 410 in the repeated cycles shown as C and E in FIG. 5), FIG. 5 illustrates a linear SiO₂ etch rate (ER), which demonstrated that the application of EB initiates the removal of the functionalized SiO₂. The ER difference between C and E is possibly due to a chamber memory effect that may be caused by residual reactants on the chamber walls, and that participated in the SiO₂ etching reactions.

For a situation where EB and Ar/CF₄/O₂ precursors are used to expose the SiO₂ surface (operation 415 shown as F in FIG. 5), a very low SiO₂ ER is seen (<0.4 Å/min). This demonstrates that application of the remote plasma energizes injected chemical precursors, improving surface adsorption of reactants, and in combination with EB bombardment cause etching. The result of operation 420 (shown as G in FIG. 5) shows that no SiO₂ thickness change is seen for conditions where SiO₂ is only exposed to the EB.

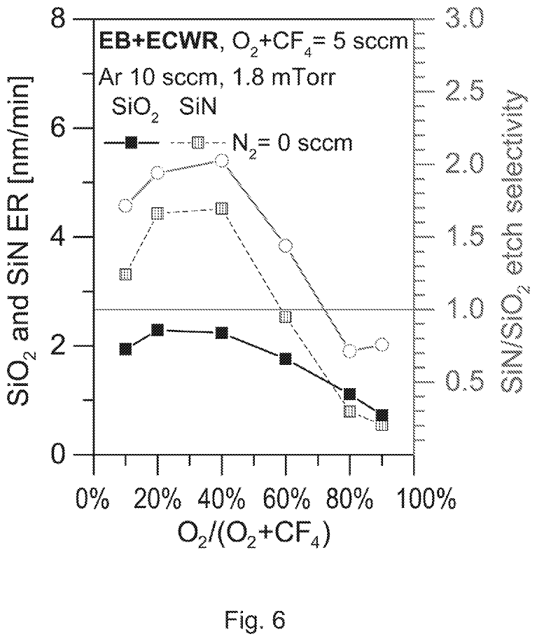

The configuration of the etching process according to certain embodiments may provide the flexibility that controls the precursor chemistry for achieving the desired etch selectivity in EBIE. FIG. 6 illustrates an example of etch selectivity of Si₃N₄ over SiO₂ for various CF₄/O₂ ratios, according to certain embodiments. In particular, FIG. 6 illustrates the co-introduction of remote plasma and EB with varied CF₄/O₂ ratios relating to the ER of SiO₂ and Si₃N₄. As illustrated in FIG. 6, the etch selectivity of Si₃N₄ over SiO₂ may be crucial for repairing defective deep ultraviolet (DUV) lithography photomasks, where EBIE removes the flawed Si₃N₄ absorber with the minimum damage on the underlying quartz substrate. On the other hand, an etch selectivity of SiO₂ over Si₃N₄ may be useful for pattern transfer on structures involving electronic materials. The results show that for the CF₄ rich regime, the process may achieve etching of Si₃N₄ with a selectivity relative to SiO₂ of greater than 1. On the other hand, for the O₂ rich regime, the materials etching selectivity may be reversed, and the SiO₂ ER may be greater than that of Si₃N₄. The results indicate various possibilities for materials etching selectivity control including, for example, manipulating the relative flow rates of injected chemical precursors to control effective precursor chemistry of adsorbates on a substrate and achieve the desired materials etching selectivity.

Although the setup of certain embodiments described herein implemented a flood gun 105 and a plasma source 110 that consisted of a specific ECWR plasma source with a neutralization plate 120, this application is not restricted to this particular embodiment and may be valid for other combinations of EB and remote plasma sources. For instance, according to certain embodiments, the EB sources may include scanning electron microscopy (SEM) or hollow-cathode electron sources, along with others. In other embodiments, the plasma sources may be based on inductively coupled plasma (ICP), capacitively coupled plasma (CCP), helical resonator or helicon plasma, electron cycle resonance (ECR), or Toroidal and microwave-based plasma sources.

Additionally, in certain embodiments, the procedure of using a sequence of remote plasma surface treatment followed by EB irradiation to achieve ALE of SiO₂ may also be applied to other semiconductor materials. For example, according to certain embodiments, other semiconductor materials may include GaAs and others, ternary compound semiconductors, and materials that pertain to DUV and extreme ultraviolet (EUV) lithography photomasks, along with others. For instance, Si, SiGe, Si₃N₄, titanium dioxide (TiO₂), titanium nitride (TiN), SiOCH, HfO₂, nitrided hafnium silicate (HfSiON), hafnium silicate (HfSiOₓ), zirconium dioxide (ZrO₂), lanthanum oxide (La₂O₃), lanthanum silicate (LaSiOₓ), lanthanum aluminate (LaAlOₓ), ruthenium (Ru), molybdenum (Mo), and nickel (Ni) are materials that may be processed using the approaches described herein.

In other embodiments, the precursor mixture may be based on a combination of tetrafluoromethane (CF₄), oxygen (O₂), and argon (Ar). However, in some embodiments, CF₄ may be substituted by other hydrofluorocarbon or fluorocarbon precursors, for example, trifluoromethane (CHF₃), difluoromethane (CF₂H₂), fluoromethane (CH₃F), methane (CH₄), hexafluoroethane (C₂F₆), pentafluoroethane (C₂HF₅), and many other precursor molecules CₓF_{y}H_{z} of variable composition and structure. In other embodiments, sources of other halogen reactants including, for example, chlorine gas (Cl₂), hydrogen chloride (HCl), and hydrogen bromide (HBr) may also be employed, depending on the material to be etched. According to certain embodiments, instead of oxygen, the use of other molecules may be advantageous (e.g. hydrogen (H₂), nitrogen (N₂), carbon dioxide (CO₂), and their mixtures). According to some embodiments, Ar may be used as a carrier and dilution gas to minimize the damage to the filament in the flood gun, which can be omitted or be replaced with other inert gases, for example, helium (He), neon (Ne), and xenon (Xe).

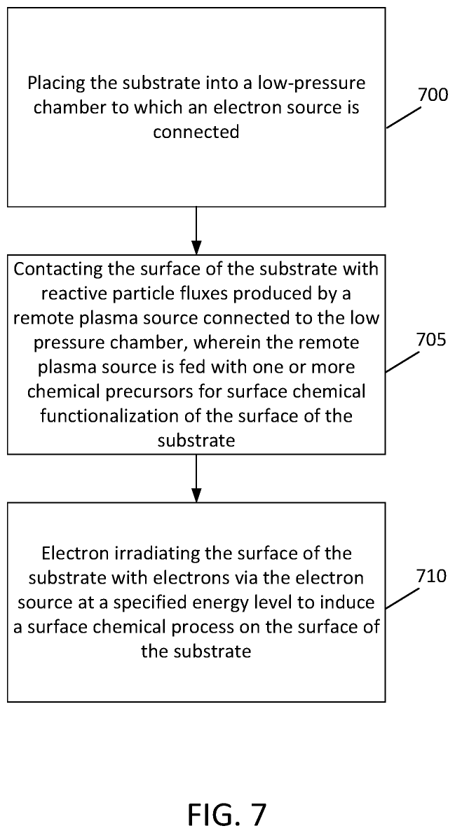

FIG. 7 illustrates an example flow diagram of a method, according to certain example embodiments. In an example embodiment, the method of FIG. 7 may be performed by a reactor. For instance, in an example, the method of FIG. 7 may be performed by a reactor similar to reactor 100 illustrated in FIG. 1.

According to certain example embodiments, the method of FIG. 7 may include, at 700, placing the substrate into a low-pressure chamber to which an electron source is connected. At 705, the method may include contacting the surface of the substrate with reactive particle fluxes produced by a remote plasma source connected to the low-pressure chamber. In certain embodiments, the remote plasma source may be fed with one or more chemical precursors for surface chemical functionalization of the surface of the substrate. In some example embodiments, this operation may include contacting the surface of the substrate with neutral species generated from a remote plasma source. Further, at 710, the method may include electron irradiating the surface of the substrate with electrons via the electron source at a specified energy level to induce a surface chemical process on the surface of the substrate.

According to certain embodiments, the method may also include patterning the surface of the substrate under low pressure with an electron beam via the electron source to produce a patterned substrate surface. According to other embodiments, contacting the surface of the substrate and electron irradiating the surface of the substrate may be performed sequentially or simultaneously. According to some embodiments, sequentially contacting and electron irradiating the surface of the substrate may include exposing the surface of the substrate to the reactive particle fluxes prior to the electron irradiating. In certain embodiments, at least one of the one or more chemical precursors comprises at least one of tetrafluoromethane, oxygen, and argon. In some embodiments, the reactive particle fluxes may be generated remotely. In other embodiments, the electron source may include a scanning electron microscopy instrument or a hollow-cathode electron source.

According to certain embodiments, the reactive particle fluxes may be produced from an inductively coupled plasma generator, a capacitively coupled plasma, a helical resonator, an electron cyclotron resonance, or a Toroidal and microwave-based remote plasma source, and alternatively also plasma sources operating at elevated pressure (e.g. atmospheric pressure plasma jets, dielectric barrier discharges, and others with carefully controlled gas flow and transport of reactive particle fluxes to the sample surface). According to some embodiments, contacting the surface of the substrate with the reactive particle fluxes of the remote plasma, and electron irradiating the surface of the substrate may be performed in one or more cycles. According to other embodiments, in each cycle, application of the reactive particle fluxes and the electron irradiating may be performed separately or in combination. In certain embodiments, the substrate may be selected from the group consisting of SiO₂, GaAs, a ternary compound semiconductor, Si, SiGe, Si₃N₄, titanium dioxide (TiO₂), aluminum oxide (Al₂O₃), titanium nitride (TiN), SiOCH, HfO₂, nitrided hafnium silicate (HfSiON), hafnium silicate (HfSiOx), zirconium dioxide (ZrO₂), lanthanum oxide (La₂O₃), lanthanum silicate (LaSiOx), lanthanum aluminate (LaAlOx), cobalt (Co), tantalum (Ta), ruthenium (Ru), molybdenum (Mo), nickel (Ni), and various alloys of these metals.

In some example embodiments, an apparatus (e.g., reactor of FIG. 1) may include means for performing a method, a process, or any of the variants discussed herein. Examples of the means may include a reactor for causing the performance of the operations.

Certain example embodiments may be directed to an apparatus that includes means for placing a substrate into a low-pressure chamber to which an electron source is connected. The apparatus may also include means for contacting the surface of the substrate with reactive particle fluxes produced by a remote plasma source connected to the low-pressure chamber. In certain embodiments, the remote plasma source is fed with one or more chemical precursors for surface chemical functionalization of the surface of the substrate. The apparatus may further include means for electron irradiating the surface of the substrate with electrons via the electron source at a specified energy level to induce a surface chemical process on the surface of the substrate.

Certain example embodiments described herein provide several technical improvements, enhancements, and/or advantages. In some example embodiments, it may be possible to enhance the range of chemical precursors that may be used to enable EBIE. Conventional approaches require an etchant that spontaneously adsorbs on a substrate for conducting ESD, and are limited to a small number of available precursors (e.g. XeF₂) and electron bombardment. Certain conventional approaches may also encounter Si surface damage induced by ion bombardment in the CF₄ plasma with several discharge pressures, suggesting that the sheath potential can be produced from 0.5 nm (500 mTorr) to 1.6 nm (10 mTorr) SiFx (x=1-3) reactive layers on the crystal Si substrate. Additionally, plasma-enhanced ALE has shown that the use of CHF₃ and C₄F₈ at the surface functional step may result in undesired Si thickness loss up to 0.2 nm per cycle.

However, the configuration of certain embodiments may exploit a remote plasma source that energizes and dissociates the injected precursors to maximize the surface adsorption on a substrate. Additionally, certain embodiments demonstrate that the combined action of a 1-keV EB and Ar/CF₄/O₂ remote plasma etched SiO₂ at a constant rate as a function of time. Moreover, the CF₄/O₂ ratio in the remote plasma may be used to adjust the chemical surface functionalization of SiO₂ (e.g., to optimize the ER difference between SiO₂ and Si₃N₄). According to other embodiments, it may be possible to provide a new method for atomic-scale control in the fabrication of advanced material structures (e.g., as needed in the transfer of patterns into electronic materials without any damage, repairing defective DUV or EUV lithography photomasks, and numerous other applications).

One skilled in the art will readily understand that the examples discussed above may be practiced with procedures in a different order, and/or with hardware elements in configurations, which are different than those which are disclosed. Therefore, although the invention has been described based upon these example embodiments, it would be apparent to those of skill in the art that certain modifications, variations, and alternative constructions would be apparent, while remaining within the spirit and scope of example embodiments.

### PARTIAL GLOSSARY

ALE Atomic Layer Etching

EB Electron Beam

EBIE Electron Beam-Inducing Etching

ESD Electron-Stimulated Desorption

EWCR Electron Cyclotron Wave Resonance

SEM Scanning Electron Microscopy

UHV Ultra High Vacuum

We claim:

1. A method for treating a surface of a substrate, comprising:
placing the substrate into a low-pressure chamber to which an electron source is connected;
contacting the surface of the substrate with reactive particle fluxes produced by a remote plasma source connected to the low-pressure chamber, wherein the remote plasma source is fed with one or more chemical precursors for surface chemical functionalization of the surface of the substrate; and
electron irradiating the surface of the substrate with electrons via the electron source at a specified energy level to induce a surface chemical process on the surface of the substrate.

2. The method for treating the surface of the substrate according to claim 1, further comprising:
patterning the surface of the substrate under low pressure with an electron beam via the electron source to produce a patterned substrate surface.

3. The method for treating the surface of the substrate according to claim 1, wherein contacting the surface of the substrate and electron irradiating the surface of the substrate are performed sequentially or simultaneously.

4. The method for treating the surface of the substrate according to claim 3, wherein sequentially contacting and electron irradiating the surface of the substrate comprises exposing the surface of the substrate to the reactive particle fluxes prior to the electron irradiating.

5. The method for treating the surface of the substrate according to claim 1, wherein one of the one or more chemical precursors comprises at least one of tetrafluoromethane, oxygen, and argon.

6. The method for treating the surface of the substrate according to claim 1, wherein the reactive particle fluxes are generated remotely.

7. The method for treating the surface of the substrate according to claim 1, wherein the electron source comprises a scanning electron microscopy or a hollow-cathode electron source.

8. The method for treating the surface of the substrate according to claim 1, wherein the reactive particle fluxes are produced from an inductively coupled plasma generator, a capacitively coupled plasma, a helical resonator, an electron cyclotron resonance, a Toroidal and microwave-based remote plasma source, atmospheric pressure plasma jets, or dielectric barrier discharges.

9. The method for treating the surface of the substrate according to claim 1, wherein contacting the surface of the substrate with the reactive particle fluxes, and electron irradiating the surface of the substrate is performed in one or more cycles.

10. The method for treating the surface of the substrate according to claim 9, wherein in each cycle, application of the reactive particle fluxes and the electron irradiating is performed separately or in combination.

11. The method for treating the surface of the substrate according to claim 1, wherein the substrate is a material selected from the group consisting of:
SiO₂, GaAs, a ternary compound semiconductor, Si, SiGe, Si₃N₄, titanium dioxide (TiO₂), aluminum oxide (Al₂O₃), titanium nitride (TiN), SiOCH, HfO₂, nitrided hafnium silicate (HfSiON), hafnium silicate (HfSiOx), zirconium dioxide (ZrO₂), lanthanum oxide (La₂O₃), lanthanum silicate (LaSiOx), lanthanum aluminate (LaAlOx), cobalt (Co), tantalum (Ta), ruthenium (Ru), molybdenum (Mo), nickel (Ni), and various alloys of these metals.

12. An apparatus for treating a surface of a substrate, comprising:
an electron source configured to irradiate the surface of the substrate with electrons at a specified energy level to induce a surface chemical process on the surface of the substrate;
a remote plasma source configured to supply reactive particle fluxes to contact the surface of the substrate, wherein the remote plasma source is fed with one or more chemical precursors for surface chemical functionalization of the surface of the substrate;
a differential pumping unit disposed at an outlet of the electron source; and
a neutralization or optical isolation plate adjacent to the remote plasma source.

13. The apparatus for patterning the surface of the substrate according to claim 12, wherein the reactive particle fluxes are produced from a chemical precursor.

14. The apparatus for patterning the surface of the substrate according to claim 13, wherein the one or more chemical precursors comprise at least one of tetrafluoromethane, oxygen, argon, trifluoromethane, difluoromethane, fluoromethane, methane, hexafluoroethane, pentafluoroethane, chlorine gas, hydrogen chloride, hydrogen bromide, hydrogen, nitrogen, carbon dioxide, helium, neon, and xenon.

15. The apparatus for patterning the surface of the substrate according to claim 12, wherein the electron source comprises a scanning electron microscopy or a hollow-cathode electron source.

16. The apparatus for patterning the surface of the substrate according to claim 12, wherein the reactive particle fluxes are produced from an inductively coupled plasma generator, a capacitively coupled plasma, a helical resonator, an electron cyclotron resonance, a Toroidal and microwave-based remote plasma source, atmospheric pressure plasma jets, or dielectric barrier discharges.

17. The apparatus for patterning the surface of the substrate according to claim 12, wherein the substrate is a material selected from the group consisting of:
SiO₂, GaAs, a ternary compound semiconductor, Si, SiGe, Si₃N₄, titanium dioxide (TiO₂), aluminum oxide (Al₂O₃), titanium nitride (TiN), SiOCH, HfO₂, nitrided hafnium silicate (HfSiON), hafnium silicate (HfSiOx), zirconium dioxide (ZrO₂), lanthanum oxide (La₂O₃), lanthanum silicate (LaSiOx), lanthanum aluminate (LaAlOx), cobalt (Co), tantalum (Ta), ruthenium (Ru), molybdenum (Mo), nickel (Ni), and various alloys of these metals.

18. An apparatus for treating a surface of a substrate, comprising:
means for placing a substrate into a low-pressure chamber to which an electron source is connected;
means for contacting the surface of the substrate with reactive particle fluxes produced by a remote plasma source connected to the low-pressure chamber, wherein the remote plasma source is fed with one or more chemical precursors for surface chemical functionalization of the surface of the substrate; and
means for electron irradiating the surface of the substrate with electrons via the electron source at a specified energy level to induce a surface chemical process on the surface of the substrate.

19. The apparatus for treating the surface of the substrate according to claim 18, further comprising:
means for patterning the surface of the substrate under low pressure with an electron beam via the electron source to produce a patterned substrate surface.

20. The apparatus for treating the surface of the substrate according to claim 18, wherein contacting the surface of the substrate and electron irradiating the surface of the substrate are performed sequentially or simultaneously.
